(19) United States
(12) Patent Application Publication
(10) Pub. No.: US 2023/0010178 A1
(43) Pub. Date: Jan. 12, 2023

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 17/809,384

(22) Filed: Jun. 28, 2022

(30) Foreign Application Priority Data
Jul. 6, 2021 (JP) 2021-112143

(51) Int. Cl. H01J 37/32; H01P 5/103

(52) U.S. Cl. CPC H01J 37/32082; H01J 37/3244; H01P 5/103

(57) ABSTRACT

A plasma processing apparatus includes a chamber providing a substrate processing space, a conductive upper shower head providing a plurality of gas holes and provided above the substrate processing space, a conductive lower shower plate providing through holes connected to the substrate processing space and provided under the upper shower head and above the substrate processing space, an electromagnetic wave introduction part formed of a dielectric material, a waveguide extending in the circumferential direction to surround the upper shower head and the electromagnetic wave introduction part and connected to the electromagnetic wave introduction part, and a coaxial line including a central conductor and an outer conductor and provided to supply electromagnetic waves to the waveguide. The coaxial line extends away from the central axis. The central conductor is connected to a wall surface that defines the waveguide at a position away from the central axis.

### CROSS-REFERENCE TO RELATED APPLICATION

This application is based upon and claims the benefit of priority from Japanese Patent Application No. 2021-112143, filed on Jul. 6, 2021, the entire contents of which are incorporated herein by reference.

### TECHNICAL FIELD

An exemplary embodiment of the present disclosure relates to a plasma processing apparatus.

### BACKGROUND

In manufacturing an electronic device, a plasma processing apparatus is used. A type of plasma processing apparatus is described in Patent Document 1. The plasma processing apparatus described in Patent Document 1 includes a processing container, a stage, an upper electrode, an introduction part, a waveguide part, a radio-frequency power supply, a dielectric plate, and a gas supply.

The stage is provided within the processing container. The upper electrode is provided above the space in the processing container. The introduction part is an introduction part for radio-frequency waves. The radio-frequency waves are VHF waves or UHF waves. The introduction part is provided at a lateral end of the space in the processing container and extends in the circumferential direction around the central axis of the processing container. The waveguide part is configured to supply radio-frequency waves to the introduction part. The waveguide part includes a resonator that provides a waveguide. The waveguide of the resonator extends in the circumferential direction around the central axis and extends in the direction in which the central axis extends to be connected to the introduction part. The waveguide part further includes a first coaxial waveguide and a plurality of second coaxial waveguides. The radio-frequency power supply is connected to the waveguide of the resonator via the first coaxial waveguide and the plurality of second coaxial waveguides. The first coaxial waveguide extends on the central axis of the processing container, and the plurality of second coaxial waveguides extend radially from the first coaxial waveguide.

The dielectric plate is provided below the upper electrode so as to form a gap with the upper electrode. The dielectric plate constitutes a gas shower plate. The gas supply is connected to a gap provided between the upper electrode and the dielectric plate via a pipe. The pipe extends away from the central axis of the processing container.

### PRIOR ART DOCUMENT

### Patent Document

Patent Document 1: Japanese Laid-Open Patent Publication No. 2020-92031

### SUMMARY

According to one embodiment of the present disclosure, there is provided a plasma processing apparatus including: a chamber configured to provide therein a substrate processing space; an upper shower head that is conductive, provides a plurality of gas holes, and is provided above the substrate processing space; a lower shower plate that is conductive, provides a plurality of through holes connected to the substrate processing space, and is provided under the upper shower head and above the substrate processing space, wherein the lower shower plate and the upper shower head define therebetween a plasma generation space in which plasma of a gas supplied through the plurality of gas holes is generated; an electromagnetic wave introduction part that is formed of a dielectric material and provided between the upper shower head and the lower shower plate, wherein the electromagnetic wave introduction part extends in a circumferential direction with respect to a central axis to surround the plasma generation space; a waveguide that extends in the circumferential direction with respect to the central axis to surround the upper shower head and the electromagnetic wave introduction part and is connected to the electromagnetic wave introduction part, wherein the waveguide and the plasma generation space constitute a resonator; and a coaxial line that includes a central conductor and an outer conductor and is provided to supply electromagnetic waves to the waveguide, wherein the coaxial line extends away from the central axis, and the central conductor is connected to a wall surface that defines the waveguide at a position away from the central axis.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view schematically illustrating a plasma processing apparatus according to an exemplary embodiment.

FIG. 2 is a view illustrating a portion of a lower shower plate of the plasma processing apparatus according to the exemplary embodiment in a cutaway state.

FIG. 3 is a view schematically illustrating a plasma processing apparatus according to another exemplary embodiment.

FIG. 4 is a view schematically illustrating a plasma processing apparatus according to still another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described.

In an exemplary embodiment, a plasma processing apparatus is provided. The plasma processing apparatus includes a chamber, an upper shower head, a lower shower plate, an electromagnetic wave introduction part, a waveguide, and a coaxial line. The chamber provides therein a substrate processing space. The upper shower head is conductive, provides a plurality of gas holes, and is provided above the substrate processing space. The lower shower plate is conductive, provides a plurality of through holes connected to the substrate processing space, and is provided under the upper shower head and above the substrate processing space. The lower shower plate and the upper shower plate define therebetween a plasma generation space in which plasma of a gas supplied through the through the plurality of gas holes is generated. The electromagnetic wave introduction part is formed of a dielectric material and provided between the upper shower head and the lower shower plate, wherein the electromagnetic wave introduction part extends in a circumferential direction with respect a central axis to surround the plasma generation space. The waveguide extends in the circumferential direction with respect to the central axis to surround the upper shower head and the electromagnetic wave introduction part and is connected to the electromagnetic wave introduction part. The waveguide and the plasma generation space constitute a resonator. The coaxial line includes a central conductor and an outer conductor and is provided to electromagnetic waves to the waveguide. The coaxial line extends away from the central axis, and the central conductor is connected to a wall surface that defines the waveguide at a position spaced apart from the central axis.

In the above-described embodiment, electromagnetic waves are introduced into the waveguide without using a coaxial line extending on the central axis. In addition, the waveguide and the plasma generation space constitute a resonator. Therefore, the wavelength of the electromagnetic waves propagating in the circumferential direction in the waveguide becomes infinite. As a result, a uniform electric field is generated in the circumferential direction in the resonator. Therefore, according to the above-described embodiment, it is possible to uniformly generate plasma in the circumferential direction in the plasma generation space.

In an exemplary embodiment, each of the plurality of through holes in the lower shower plate includes a lower portion on the side of the substrate processing space. The lower portion of through holes among the plurality of through holes provided nearer the center of the lower shower plate than other through holes may have a diameter smaller than that of the lower portion of the other through holes. In this embodiment, even if the density of the plasma in the plasma generation space decreases along the distance from the central axis in the radial direction, the uniformity of the density of radicals supplied to the substrate processing space is increased.

In an exemplary embodiment, the density of the plurality of through holes in the lower shower plate increases as the distance from the center of the lower shower plate increases. In this embodiment, even if the density of the plasma in the plasma generation space decreases along the distance from the central axis in the radial direction, the uniformity of the density of radicals supplied to the substrate processing space is enhanced.

In an exemplary embodiment, each of the plurality of through holes in the lower shower plate includes an upper portion on the side of the plasma generation space. The upper portion of each of the plurality of through holes may have a hollow cathode structure.

In an exemplary embodiment, the distance between the upper shower head and the lower shower plate may be 10 mm or less. In this embodiment, the distance between the upper shower head and the lower shower plate is smaller than the skin depth of the plasma. Therefore, the wavelength of standing waves in the plasma generation space becomes long. Therefore, the uniformity of the density of the plasma generated in the plasma generation space in the radial direction is enhanced. The distance between the upper shower head and the lower shower plate may be 5 mm or less.

In an exemplary embodiment, the plasma processing apparatus may further include a radio-frequency power supply. The radio-frequency power supply is configured to generate radio-frequency power having a variable frequency and is connected to the coaxial line. In this embodiment, it is possible to maintain the resonance state of electromagnetic waves in the resonator by adjusting the frequency of the radio-frequency power.

In an exemplary embodiment, the plasma processing apparatus may further include a first electric field antenna, a first wave detector, a second electric field antenna, a second wave detector, and a controller. The first electric field antenna is provided to receive electromagnetic waves in a first region of the waveguide. The first wave detector is configured to output a first signal representing a first electric field strength of the electromagnetic waves received by the first electric field antenna. The second electric field antenna is provided to receive electromagnetic waves in a second region of the waveguide. The second wave detector is configured to output a second signal representing a second electric field strength of the electromagnetic waves received by the second electric field antenna. The controller is configured to adjust the frequency of the radio-frequency power according to the first signal and the second signal so as to reduce a difference between the first electric field strength and the second electric field strength. The coaxial line is connected so as to introduce electromagnetic waves into the waveguide from the first region. The direction in which the second region is located with respect to the central axis is opposite to the direction in which the first region is located with respect to the central axis. In this embodiment, it is possible to adjust the frequency of the radio-frequency power according to the first signal and the second signal so as to ensure the uniformity of the electric field strength along the circumferential direction in the waveguide.

In an exemplary embodiment, the plasma processing apparatus may further include a movable part configured to cause resonance of electromagnetic waves in the resonator by adjusting the length of the waveguide.

In an exemplary embodiment, the upper shower head may include an upper shower plate and an upper wall. The upper shower plate provides the plurality of gas holes. The upper wall is provided on the upper shower plate. The upper wall and the upper shower plate define therebetween a gas diffusion space that communicates with the plurality of gas holes, and the upper wall may provide a gas introduction port connected to the gas diffusion space on the central axis.

In an exemplary embodiment, the plasma processing apparatus may further include a gas source of a cleaning gas that is connected to the gas introduction port via a pipe extending on the central axis.

] In an exemplary embodiment, the plasma processing apparatus may further include a gas source of a film forming gas that is connected to the gas introduction port via the pipe.

In an exemplary embodiment, the lower shower plate may have a ground potential.

In an exemplary embodiment, the wall surface to which the central conductor of the coaxial line is connected may be a side surface or a top surface of the upper shower head.

Hereinafter, various exemplary embodiments will be described in detail with reference to the drawings. In respective drawings, the same or corresponding components will be denoted by the same reference numerals.

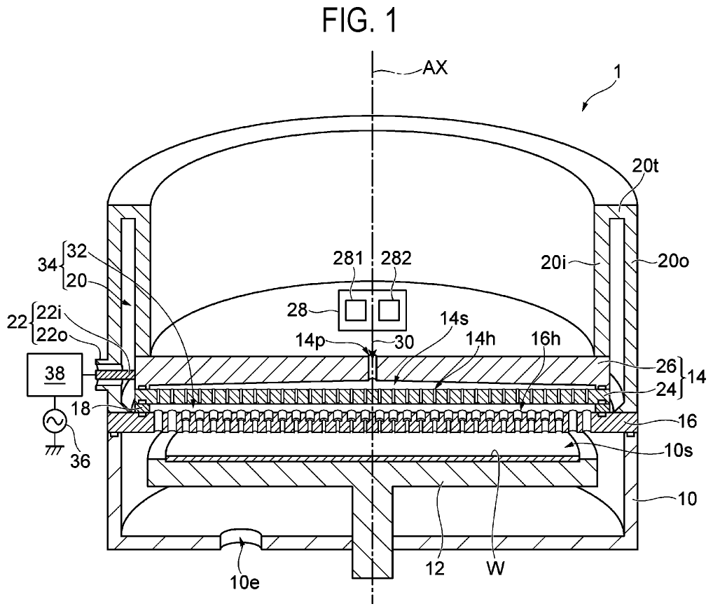

FIG. 1 is a view schematically illustrating a plasma processing apparatus according to an exemplary embodiment. The plasma processing apparatus 1 illustrated in FIG. 1 includes a chamber 10, a substrate support 12, an upper shower head 14, a lower shower plate 16, an electromagnetic wave introduction part 18, a waveguide 20, and a coaxial line 22.

The chamber 10 provides therein a substrate processing space 10s. The chamber 10 is made of a metal such as aluminum and grounded. The chamber 10 may have a substantially cylindrical shape that is open at the upper end thereof. The central axis of each of the chamber 10 and the substrate processing space 10s is the axis AX. The chamber 10 may have a corrosion-resistant film on the surface thereof. The corrosion-resistant film may be an yttrium oxide film, an yttrium oxyfluoride film, an yttrium fluoride film, or a ceramic film containing yttrium oxide, yttrium fluoride, or the like.

The bottom of the chamber 10 provides an exhaust port 10e. An exhaust apparatus is connected to the exhaust port 10e. The exhaust apparatus may include a dry pump and/or a vacuum pump such as a turbo molecular pump and an automatic pressure control valve.

The substrate support 12 is provided within the substrate processing space 10s. The substrate support 12 is configured to support a substrate W placed on the top surface thereof substantially horizontally. The substrate support 12 has a substantially disk-like shape. The central axis of the substrate support 12 is the axis AX.

The upper shower head 14 is conductive. The upper shower head 14 is made of a metal such as aluminum. The upper shower head 14 is provided above the substrate processing space 10s. The upper shower head 14 provides a plurality of gas holes 14h. The diameter of the plurality of gas holes 14h may be about 0.3 mm.

In an embodiment, the upper shower head 14 may include an upper shower plate 24 and an upper wall 26. The upper shower plate 24 is conductive. The upper shower plate 24 is made of a metal such as aluminum. The upper shower plate 24 has a substantially disk-like shape. The central axis of the upper shower plate 24 is the axis AX. The upper shower plate 24 provides a plurality of gas holes 14h. The plurality of gas holes 14h penetrate the upper shower plate 24 in the plate thickness direction.

The upper wall 26 is provided on the upper shower plate 24. The upper wall 26 is conductive. The upper wall 26 is made of a metal such as aluminum. The upper wall 26 has a substantially disk-like shape. The central axis of the upper wall 26 is the axis AX. The peripheral edge of the bottom surface of the upper wall 26 is in contact with the upper shower plate 24. Accordingly, the upper wall 26 is electrically connected to the upper shower plate 24. The bottom surface of the upper wall 26 is spaced apart from the upper shower plate 24 on the inner side of the peripheral edge thereof. The position of the bottom surface of the upper wall 26 in the height direction may be formed so as to decrease as the distance in the radial direction from the axis AX increases.

The upper wall 26 and the upper shower plate 24 define a gas diffusion space 14s therebetween. The plurality of gas holes 14h extend downward from the gas diffusion space 14s. The upper wall 26 provides a gas introduction port 14p. The gas introduction port 14p extends downward on the axis AX from the top surface of the upper wall 26 and is connected to the gas diffusion space 14s.

In an embodiment, the plasma processing apparatus 1 may further include a gas supply 28. The gas supply 28 may include a gas source 281 and a gas source 282. The gas source 281 is a source of a processing gas used in the processing of a substrate W. The processing gas may be a film forming gas. The gas source 282 is a source of a cleaning gas. The cleaning gas is used in cleaning the wall surface within the chamber 10. The gas source 281 and the gas source 282 are connected to the gas introduction port 14p via a pipe 30. The pipe 30 extends on the axis AX.

The lower shower plate 16 is provided under the upper shower head 14 and above the substrate processing space 10s. The lower shower plate 16 closes the upper end opening of the chamber 10. The peripheral edge of the lower shower plate 16 may be located on the top portion of the chamber 10.

The lower shower plate 16 is conductive. The lower shower plate 16 is made of a metal such as aluminum. The lower shower plate 16 is grounded and has a ground potential. The lower shower plate 16 has a substantially disk-like shape. The central axis of the lower shower plate 16 is the axis AX.

The lower shower plate 16 provides a plurality of through holes 16h. The plurality of through holes 16h penetrate the lower shower plate 16 in the plate thickness direction. The plurality of through holes 16h are connected to the substrate processing space 10s. The lower shower plate 16 and the upper shower plate 24 of the upper shower head 14 define a plasma generation space 32 therebetween. The plasma generation space 32 is the space in which plasma of gas supplied through the plurality of gas holes 14h is generated.

In an embodiment, the distance between the upper shower plate 24 of the upper shower head 14 and the lower shower plate 16, that is, the length of the plasma generation space 32 in the vertical direction may be 10 mm or less. The distance between the upper shower plate 24 of the upper shower head 14 and the lower shower plate 16 may be 5 mm or less.

The electromagnetic wave introduction part 18 is made of a dielectric material such as quartz, aluminum nitride, or aluminum oxide. The electromagnetic wave introduction part 18 is provided between the upper shower plate 24 of the upper shower head 14 and the lower shower plate 16. The electromagnetic wave introduction part 18 surrounds the plasma generation space 32. The central axis of the electromagnetic wave introduction part 18 is the axis AX. The electromagnetic wave introduction part 18 extends in the circumferential direction with respect to the axis AX. The electromagnetic wave introduction part 18 is substantially ring-shaped. The electromagnetic wave introduction part 18 introduces electromagnetic waves propagating from the waveguide 20 into the plasma generation space 32. The electromagnetic waves are radio-frequency waves such as VHF waves or UHF waves, and are generated by a radio-frequency power supply to be described later.

The waveguide 20 extends in the circumferential direction with respect to the axis AX so as to surround the upper shower head 14 and the electromagnetic wave introduction part 18. The waveguide 20 has a substantially cylindrical shape. The waveguide 20 is connected to the electromagnetic wave introduction part 18. The waveguide 20 and the plasma generation space 32 constitute a resonator 34. The length of the waveguide 20 (in the plasma processing apparatus 1, the vertical length of the waveguide 20) is set such that electromagnetic waves resonate in the resonator 34. That is, the length of the waveguide 20 is set such that the inductance when the waveguide 20 is viewed from the electromagnetic wave introduction part 18 and the capacitance when the plasma generation space 32 is viewed from the electromagnetic wave introduction part 18 cause resonance of the electromagnetic waves.

The waveguide 20 may be defined by an inner wall 20i, an outer wall 20o, and an upper wall 20t. The inner wall 20i, the outer wall 20o, and the upper wall 20t are made of a conductor. The inner wall 20i, the outer wall 20o, and the upper wall 20t are made of a metal such as aluminum. Each of the inner wall 20i and the outer wall 20o has a substantially cylindrical shape. The central axis of each of the inner wall 20i and the outer wall 20o is the axis AX. The inner wall 20i is provided inside the outer wall 20o. The lower end of the inner wall 20i is in contact with the top surface of the peripheral edge of the upper wall 26 of the upper shower head 14. The lower end of the outer wall 20o is in contact with the top surface of the peripheral edge of the lower shower plate 16. The upper wall 20t has a ring shape and closes an opening between the upper end of the inner wall 20i and the upper end of the outer wall 20o.

The coaxial line 22 has a central conductor 22i and an outer conductor 22o. The coaxial line 22 extends away from the axis AX. The coaxial line 22 is provided so as to supply electromagnetic waves to the waveguide 20. The coaxial line 22 is connected between the radio-frequency power supply 36 and the waveguide 20. The radio-frequency power supply 36 is a power supply that generates radio-frequency power. In an embodiment, the radio-frequency power supply 36 may be configured to generate radio-frequency power having a variable frequency. The radio-frequency power generated by the radio-frequency power supply 36 is supplied to the waveguide 20 via the coaxial line 22 as electromagnetic waves via a matcher 38. The matcher 38 includes a matching circuit configured to match the impedance of the load of the radio-frequency power supply 36 with the output impedance of the radio-frequency power supply 36.

The outer conductor 22o has a substantially cylindrical shape. The central conductor 22i is provided inside the outer conductor 22o. The central conductor 22i is provided coaxially with the outer conductor 22o. The coaxial line 22 extends from the exterior of the waveguide 20, that is, the exterior of the outer wall 20o toward the waveguide 20. The end of the outer conductor 22o is connected to the outer wall 20o. The end of the central conductor 22i is connected to the wall surface defining the waveguide 20 at a position spaced apart from the axis AX. In the plasma processing apparatus 1, the end of the central conductor 22i is connected to the upper shower head 14 at a position spaced apart from the axis AX. Specifically, the end of the central conductor 22i is connected to the side surface of the upper wall 26 of the upper shower head 14.

In the plasma processing apparatus 1, the electromagnetic waves are introduced into the waveguide 20 without using a coaxial line extending on the axis AX. The waveguide 20 and the plasma generation space 32 constitute a resonator 34. Therefore, the wavelength of electromagnetic waves propagating in the circumferential direction of the waveguide 20 becomes infinite. As a result, a uniform electric field is generated in the resonator 34 in the circumferential direction. Therefore, the plasma processing apparatus 1 is able to uniformly generate plasma in the circumferential direction in the plasma generation space 32.

Furthermore, in the plasma processing apparatus 1, since the plasma generation space 32 is defined between the upper shower head 14 and the lower shower plate 16, the volume of the plasma generation space 32 is small. Therefore, the electromagnetic waves are less likely to be absorbed in the plasma generation space 32, and a Q value of the resonator 34 is enhanced. Therefore, even when electromagnetic waves are introduced into the waveguide 20 from a single location spaced apart from the axis AX, a uniform electromagnetic field distribution is obtained in the circumferential direction in the resonator 34, and plasma having a uniform density in the circumferential direction is obtained.

As described above, the distance between the upper shower plate 24 of the upper shower head 14 and the lower shower plate 16, that is, the length of the plasma generation space 32 in the vertical direction may be 10 mm or less. In this case, the distance between the upper shower head 14 and the lower shower plate 16 is smaller than the skin depth of the plasma. When the distance between the upper shower plate 24 and the lower shower plate 16 is smaller than the skin depth of the plasma, electromagnetic waves propagate in the plasma generation space 32 in a TEM mode. When the distance between the upper shower head 14 and the lower shower plate 16 is sufficiently larger than the skin depth of the plasma, electromagnetic waves propagate in the plasma generation space 32 in a surface wave mode. The wavelength of the electromagnetic waves in the TEM mode is longer than the wavelength of the electromagnetic waves in the surface wave mode. Therefore, in the plasma processing apparatus 1, the wavelength of standing waves in the plasma generation space 32 becomes long. Therefore, the uniformity of the density of the plasma generated in the plasma generation space 32 in the radial direction is enhanced. As described above, the distance between the upper shower plate 24 of the upper shower head 14 and the lower shower plate 16 may be 5 mm or less.

In addition, in the plasma processing apparatus 1, the gas from the gas supply 28 may be supplied into the chamber 10 via the pipe 30 extending on the axis AX. Therefore, it is possible to perform a uniform process on a substrate W. In addition, it is possible to uniformly clean the wall surface within the chamber 10.

Furthermore, since the lower shower plate 16 is grounded, the substrate processing space 10s is shielded from electromagnetic waves. Accordingly, since the influence of standing waves on the side of the substrate processing space 10s can be ignored, it is possible to shorten the distance between the lower shower plate 16 and the substrate support 12. With the lower shower plate 16, diffusion of plasma into the substrate processing space 10s is suppressed. Accordingly, it is possible to suppress the amount of ions incident on a substrate W and the energy of the ions incident on a substrate W. Thus, it is possible to carry out an excellent process for a substrate W by radicals.

As described above, the radio-frequency power supply 36 may be configured to generate radio-frequency power having a variable frequency. In this case, by adjusting the frequency of the radio-frequency power, it is possible to maintain the resonance state of the electromagnetic waves in the resonator 34.

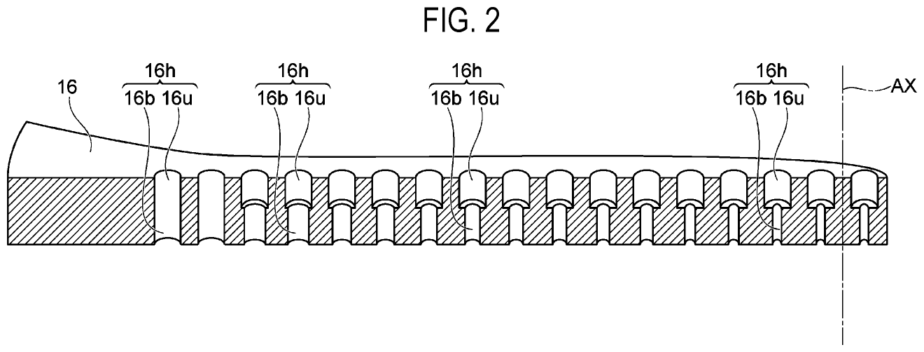

Hereinafter, reference is made to FIG. 2. FIG. 2 is a view illustrating a portion of a lower shower plate of the plasma processing apparatus according to an exemplary embodiment in a cutaway state. As illustrated in FIG. 2, each of the plurality of through holes 16h in the lower shower plate 16 may include a lower portion 16b on the side of the substrate processing space 10s and an upper portion 16u on the side of the plasma generation space 32. In each of the plurality of through holes 16h, the lower portion 16b opens toward the substrate processing space 10s. In each of the plurality of through holes 16h, the upper portion 16u extends upward from the lower portion 16b and opens toward the plasma generation space 32.

The lower portion 16b of through holes among the plurality of through holes 16h provided nearer the center of the lower shower plate 16 than other through holes may have a diameter smaller than that of the lower portion 16b of those other through holes. For example, the lower portion 16b of each of the plurality of through holes 16h may have a diameter that increases as the distance from the axis AX increases. In this case, even when the density of the plasma in the plasma generation space 32 decreases along the distance from the axis AX in the radial direction, the uniformity of the density of the radicals supplied to the substrate processing space 10s is increased.

In an embodiment, the upper portion 16u of each of the plurality of through holes 16h may have a hollow cathode structure. In order to generate hollow cathode plasma in the upper portion 16u of each of the plurality of through holes 16h, the product of the diameter of the upper portion 16u and the pressure of the gas may be about 1.5 mm·Torr. For example, when the pressure of the gas is 0.3 Torr, the diameter of the upper portion 16u of each of the plurality of through holes 16h may be 5 mm. As described above, when the upper portion 16u of each of the plurality of through holes 16h has the hollow cathode structure, active species required for a process are efficiently generated by the high-density plasma.

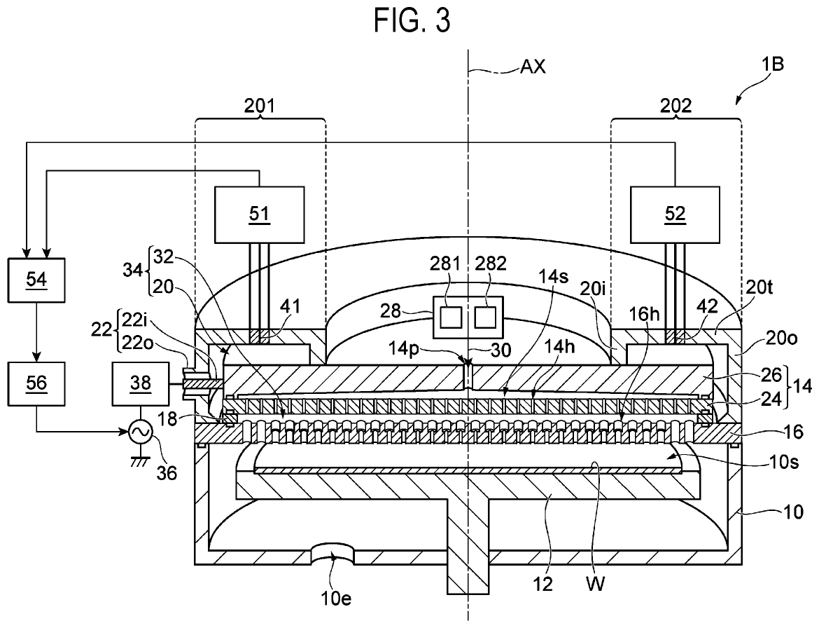

Hereinafter, a plasma processing apparatus according to another exemplary embodiment will be described with reference to FIG. 3. FIG. 3 is a diagram schematically showing a plasma processing apparatus according to another exemplary embodiment. Hereinafter, from the viewpoint of the difference between the plasma processing apparatus 1B illustrated in FIG. 3 and the plasma processing apparatus 1, the plasma processing apparatus 1B will be described.

In the plasma processing apparatus 1B, the waveguide 20 extends in the circumferential direction around the axis AX so as to surround the electromagnetic wave introduction part 18 and the upper shower head 14. The waveguide 20 is bent along the upper shower head 14, and the upper portion of the wave guide extends toward the axis AX. In the plasma processing apparatus 1B, the lower end of the inner wall 20i is in contact with the top surface of the upper wall 26.

The plasma processing apparatus 1B may further include a first electric field antenna 41, a first wave detector 51, a second electric field antenna 42, a second wave detector 52, and a controller 56.

The first electric field antenna 41 is provided to receive electromagnetic waves in the first region 201 of the waveguide 20. The coaxial line 22 is connected to introduce the electromagnetic waves from the first region 201 into the waveguide 20. The first electric field antenna 41 is provided within an opening formed in the upper wall 20t. This opening may be sealed with a resin such as polytetrafluoroethylene. The first electric field antenna 41 is connected to the first wave detector 51 via the coaxial line. The first wave detector 51 is configured to output a first signal. The first signal represents the first electric field strength of the electromagnetic waves received by the first electric field antenna 41.

The second electric field antenna 42 is provided to receive electromagnetic waves in the second region 202 of the waveguide 20. The direction in which the second region 202 is located with respect to the axis AX is opposite to the direction in which the first region 201 is located with respect to the axis AX. The second electric field antenna 42 is provided within an opening formed in the upper wall 20t. This opening may be sealed with a resin such as polytetrafluoroethylene. The second electric field antenna 42 is connected to the second wave detector 52 via the coaxial line. The second wave detector 52 is configured to output a second signal. The second signal represents the second electric field strength of the electromagnetic waves received by the second electric field antenna 42.

The controller 56 is configured to adjust the frequency of the radio-frequency power generated by the radio-frequency power supply 36 according to the first signal and the second signal so as to reduce the difference between the first electric field strength and the second electric field strength. In an embodiment, the controller 56 may be configured to adjust the frequency of the radio-frequency power generated by the radio-frequency power supply 36 according to the signal generated by a difference amplifier 54. The difference amplifier 54 outputs a signal generated by amplifying a difference signal between the first signal and the second signal to the controller 56.

With the plasma processing apparatus 1B, it is possible to adjust the frequency of the radio-frequency power according to the first signal and the second signal so as to ensure the uniformity of the electric field strength along the circumferential direction in the waveguide 20.

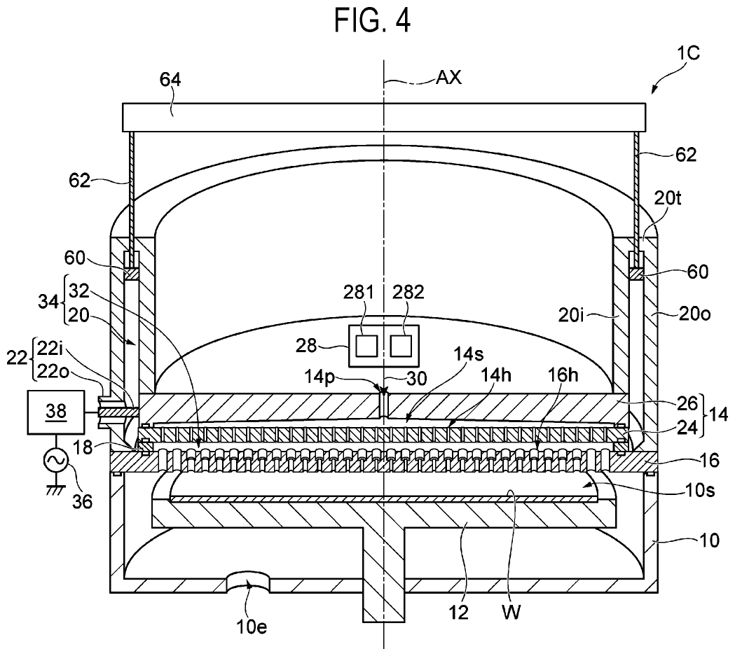

Hereinafter, a plasma processing apparatus according to still another exemplary embodiment will be described with reference to FIG. 4. FIG. 4 is a view schematically illustrating a plasma processing apparatus according to still another exemplary embodiment. Hereinafter, from the viewpoint of the difference between the plasma processing apparatus 1C illustrated in FIG. 4 and the plasma processing apparatus 1, the plasma processing apparatus 1C will be described.

The plasma processing apparatus 1C further includes a movable part 60. The movable part 60 is made of a conductor. The movable part 60 has a ring shape and extends in the circumferential direction in the waveguide 20. The movable part 60 is configured to adjust the length of the waveguide 20 to cause resonance of electromagnetic waves in the resonator 34. The movable part 60 may be connected to a driving apparatus 64 via one or more shafts 62. The driving apparatus 64 is configured to generate power for moving the movable part 60 up and down via the shaft 62.

Although various exemplary embodiments have been described above, the present disclosure is not limited to the exemplary embodiments described above, and various additions, omissions, substitutions, and changes may be made. In addition, elements in different embodiments may be combined to form other embodiments.

For example, in each of the plasma processing apparatuses 1 and 1C, the end of the central conductor 22i of the coaxial line 22 may be connected to the inner wall 20i. In the plasma processing apparatus 1B, the end of the central conductor 22i of the coaxial line 22 may be connected to the top surface of the upper wall 26 defining the waveguide 20.

In addition, the density of the plurality of through holes 16h in the lower shower plate 16 may increase as the distance from the center of the lower shower plate 16 increases. In this case, the diameters of the plurality of through holes 16h may be the same as each other. In this case, even when the density of the plasma in the plasma generation space 32 decreases along the distance from the axis AX in the radial direction, the uniformity of the density of the radicals supplied to the substrate processing space 10s is increased.

Each of the plasma processing apparatus 1 and the plasma processing apparatus 1C may include the above-mentioned first electric field antenna 41, first wave detector 51, second electric field antenna 42, second wave detector 52, difference amplifier 54, and controller 56.

From the foregoing, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the disclosure is indicated by the appended claims.

According to an exemplary embodiment, it is possible to uniformly generate plasma in the circumferential direction in the plasma generation space by using electromagnetic waves introduced into the waveguide without using a coaxial line extending on the central axis.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber configured to provide therein a substrate processing space;
an upper shower head that is conductive, provides a plurality of gas holes, and is provided above the substrate processing space;
a lower shower plate that is conductive, provides a plurality of through holes connected to the substrate processing space, and is provided below the upper shower head and above the substrate processing space, wherein the lower shower plate and the upper shower head define therebetween a plasma generation space in which plasma of a gas supplied through the plurality of gas holes is generated;
an electromagnetic wave introduction part that is formed of a dielectric material and provided between the upper shower head and the lower shower plate, wherein the electromagnetic wave introduction part extends in a circumferential direction with respect to a central axis to surround the plasma generation space;
a waveguide that extends in the circumferential direction with respect to the central axis to surround the upper shower head and the electromagnetic wave introduction part and is connected to the electromagnetic wave introduction part, wherein the waveguide and the plasma generation space constitute a resonator; and
a coaxial line that includes a central conductor and an outer conductor and is provided to supply electromagnetic waves to the waveguide, wherein the coaxial line extends away from the central axis, and the central conductor is connected to a wall surface that defines the waveguide at a position away from the central axis.

2. The plasma processing apparatus of claim 1, wherein each of the plurality of through holes includes a lower portion on a side of the substrate processing space, and
the lower portion of through holes among the plurality of through holes provided nearer a center of the lower shower plate than other through holes has a diameter smaller than a diameter of the lower portion of the other through holes.

3. The plasma processing apparatus of claim 2, wherein each of the plurality of through holes includes an upper portion on a side of the plasma generation space, and
the upper portion of each of the plurality of through holes has a hollow cathode structure.

4. The plasma processing apparatus of claim 3, wherein a distance between the upper shower head and the lower shower plate is 10 mm or less.

5. The plasma processing apparatus of claim 4, further comprising:
a radio-frequency power supply configured to generate radio-frequency power having a variable frequency and connected to the coaxial line.

6. The plasma processing apparatus of claim 5, further comprising:
a first electric field antenna provided to receive electromagnetic waves in a first region of the waveguide;
a first wave detector configured to output a first signal representing a first electric field strength of the electromagnetic waves received by the first electric field antenna;
a second electric field antenna provided to receive electromagnetic waves in a second region of the waveguide;
a second wave detector configured to output a second signal representing a second electric field strength of the electromagnetic waves received by the second electric field antenna; and
a controller configured to adjust a frequency of the radio-frequency power according to the first signal and the second signal so as to reduce a difference between the first electric field strength and the second electric field strength,
wherein the coaxial line is connected so as to introduce the electromagnetic waves from the first region into the waveguide, and
a direction in which the second region is located with respect to the central axis is opposite to a direction in which the first region is located with respect to the central axis.

7. The plasma processing apparatus of claim 6, further comprising:
a movable part configured to adjust a length of the waveguide to cause resonance of the electromagnetic waves in the resonator.

8. The plasma processing apparatus of claim 7, wherein the upper shower head includes:
an upper shower plate configured to provide a plurality of gas holes; and
an upper wall provided on the upper shower plate, and
wherein the upper wall and the upper shower plate define therebetween a gas diffusion space that communicates with the plurality of gas holes, and
the upper wall provides a gas introduction port connected to the gas diffusion space on the central axis.

9. The plasma processing apparatus of claim 8, further comprising:
a gas source of a cleaning gas that is connected to the gas introduction port via a pipe extending on the central axis.

10. The plasma processing apparatus of claim 9, further comprising:
a gas source of a film forming gas that is connected to the gas introduction port via the pipe.

11. The plasma processing apparatus of claim 10, wherein the lower shower plate has a ground potential.

12. The plasma processing apparatus of claim 1, wherein a density of the plurality of through holes increases as a distance from the center of the lower shower plate increases.

13. The plasma processing apparatus of claim 1, wherein each of the plurality of through holes includes an upper portion on a side of the plasma generation space, and
the upper portion of each of the plurality of through holes has a hollow cathode structure.

14. The plasma processing apparatus of claim 1, wherein a distance between the upper shower head and the lower shower plate is 10 mm or less.

15. The plasma processing apparatus of claim 1, wherein a distance between the upper shower head and the lower shower plate is 5 mm or less.

16. The plasma processing apparatus of claim 1, further comprising:
a radio-frequency power supply configured to generate radio-frequency power having a variable frequency and connected to the coaxial line.

17. The plasma processing apparatus of claim 1, further comprising:
a movable part configured to adjust a length of the waveguide to cause resonance of the electromagnetic waves in the resonator.

18. The plasma processing apparatus of claim 1, wherein the upper shower head includes:
an upper shower plate configured to provide a plurality of gas holes; and
an upper wall provided on the upper shower plate, and
wherein the upper wall and the upper shower plate define therebetween a gas diffusion space that communicates with the plurality of gas holes, and
the upper wall provides a gas introduction port connected to the gas diffusion space on the central axis.

19. The plasma processing apparatus of claim 1, wherein the lower shower plate has a ground potential.

20. The plasma processing apparatus of claim 1, wherein the wall surface to which the central conductor is connected is a side surface or a top surface of the upper shower head.
